(19) United States
(12) Patent Application Publication
(10) Pub. No.: US 2013/0162727 A1
(43) Pub. Date: Jun. 27, 2013

(54) SUBSTRATE, LIQUID EJECTION HEAD HAVING SUCH SUBSTRATE AND METHOD OF MANUFACTURING SUCH SUBSTRATE

(71) Applicant: CANON KABUSHIKI KAISHA, Tokyo (JP)

(72) Inventors: Shinan Wang, Kashiwa-shi (JP); Yasuto Kodera, Fujisawa-shi (JP)

(73) Assignee: CANON KABUSHIKI KAISHA, Tokyo (JP)

(21) Appl. No.: 13/706,464

(22) Filed: Dec. 6, 2012

(30) Foreign Application Priority Data
Dec. 21, 2011 (JP) 2011-279771

(51) Int. Cl. B41J 2/14; H01L 21/04; H01L 29/06

(52) U.S. Cl. CPC B41J 2/14201; H01L 29/06; H01L 21/04
USPC 347/71; 257/618; 438/21

(57) ABSTRACT

A substrate includes a substrate body having a semiconductor element formed thereon and at least either a recess or a protrusion formed on the surface thereof and a printed circuit formed on the substrate body and connected to the semiconductor element. At least a part of the printed circuit is formed in a region of the surface of the substrate including either the inner side surfaces of the recess or the outer side surfaces of the protrusion.

### BACKGROUND OF THE INVENTION

1. Field of the Invention

The present invention relates to a substrate having a printed circuit, to a liquid ejection head provided with such a substrate and also to a method of manufacturing such a substrate.

2. Description of the Related Art

Substrates having a substrate body provided with a semiconductor element and a printed circuit connected to the semiconductor element are known. The substrate body has a flat substrate surface and the printed circuit is formed within the flat substrate surface. The printed circuit can supply electric power to the semiconductor element from the outside of the substrate.

Such substrates are employed in liquid ejection heads (also referred to as ink jet heads) of inkjet recording apparatus. A liquid storage chamber for storing liquid is formed in the substrate body and held in communication with an ejection port. The storage chamber wall that defines the liquid storage chamber is made of a piezoelectric material and electrodes are arranged at the opposite surfaces of the storage chamber wall and connected to the printed circuit. The storage chamber wall undergoes shear deformation as a voltage is applied to the storage chamber wall by way of the printed circuit and the electrodes.

The pressure that is produced as the storage chamber wall undergoes shear deformation is utilized to eject ink in the inside of the liquid storage chamber. As the voltage being applied to the storage chamber wall is raised, the shear deformation of the storage chamber wall is increased to by turn apply higher pressure to the ink. Additionally, the storage chamber wall will be deformed quickly to apply relatively high pressure to the ink if the voltage being applied to the storage chamber wall is changed suddenly to a large extent.

Japanese Patent Application Laid-Open No. 2008-143167 discloses an instance of applying such a substrate to a so-called harmonica-type piezoelectric inkjet head. In the piezoelectric inkjet head, the openings of a plurality of liquid storage chambers are formed on the front surface and the back surface of the substrate body.

However, for a substrate having a plurality of semiconductor elements, the number of printed circuits increases as the number of semiconductor elements is raised. Since the region where printed circuits are formed is limited to within the substrate surface, the dimension each printed circuit can have in the direction perpendicular to the direction in which an electric current flows (to be referred to as “circuit width” hereinafter) tends to be reduced.

Then, as the circuit width of a printed circuit is reduced, the electric resistance of the printed circuit increases. As a result, a higher voltage can no longer be applied to the semiconductor elements and the voltage being applied to the semiconductor elements cannot be changed suddenly to a large extent.

For example, there is a tendency of increasing both the number of ejection ports and the number of liquid storage chambers for substrates to be used for inkjet heads in order to make the inkjet head capable of recording higher quality images. Then, the circuit width of each of the printed circuits on the substrate of the inkjet head inevitably needs to be reduced in order to increase the number of printed circuits to correspond to the increased number of liquid storage chambers.

If the circuit width of each printed circuit is reduced, the voltage to be applied to the storage chamber wall defining each liquid storage chamber will be reduced and, additionally, the voltage being applied to the storage chamber wall cannot be changed suddenly to a large extent. As a result, there arises a situation where the force applied to ink becomes relatively small and hence ink having a relatively high viscosity can no longer be ejected.

### SUMMARY OF THE INVENTION

According to the present invention, the above problem is dissolved by providing a substrate including: a substrate body having a semiconductor element formed thereon and at least either a recess or a protrusion formed on the surface thereof; and a printed circuit formed on the substrate body and connected to the semiconductor element; at least a part of the printed circuit being formed in a region of the surface of the substrate including either the inner side surfaces of the recess or the outer side surfaces of the protrusion.

Further features of the present invention will become apparent from the following description of exemplary embodiments with reference to the attached drawings.

### BRIEF DESCRIPTION OF THE DRAWINGS

FIGS. 1A, 1B and 1C are schematic perspective views of a substrate according to the first embodiment of the present invention, illustrating the manufacturing steps thereof.

FIGS. 2A, 2B and 2C are schematic perspective views of a substrate according to the second embodiment of the present invention, illustrating the manufacturing steps thereof.

FIGS. 3A, 3B, 3C and 3D are respectively a schematic top view of a substrate according to the third embodiment of the present invention, a top view of the substrate from which the printed circuit is omitted, an enlarged schematic perspective view of the substrate and an enlarged schematic perspective view of the substrate from which the printed circuit is omitted.

FIGS. 4A, 4B and 4C are schematic top views of a substrate according to the fourth embodiment of the present invention, illustrating the manufacturing steps thereof.

FIGS. 5A, 5B, 5C and 5D are respectively a schematic top view of a substrate according to the fifth embodiment of the present invention, an enlarged schematic perspective view of a part of the substrate, a schematic top view of the substrate from which the printed circuit is omitted and an enlarged schematic perspective view of a part of the substrate from which the printed circuit is omitted.

FIGS. 6A, 6B and 6C are schematic perspective views of a substrate according to the fifth embodiment of the present invention, illustrating the manufacturing steps thereof.

FIGS. 7A and 7B are respectively a schematic top view of a substrate according to the sixth embodiment of the present and a schematic top view of the substrate from which the printed circuit is omitted.

FIGS. 8A and 8B are respectively a schematic top view of a substrate according to the seventh embodiment of the present invention and a schematic top view of the substrate from which the printed circuit is omitted.

### DESCRIPTION OF THE EMBODIMENTS

Embodiments of the present invention will be described by referring to the accompanying drawings.

### First Embodiment

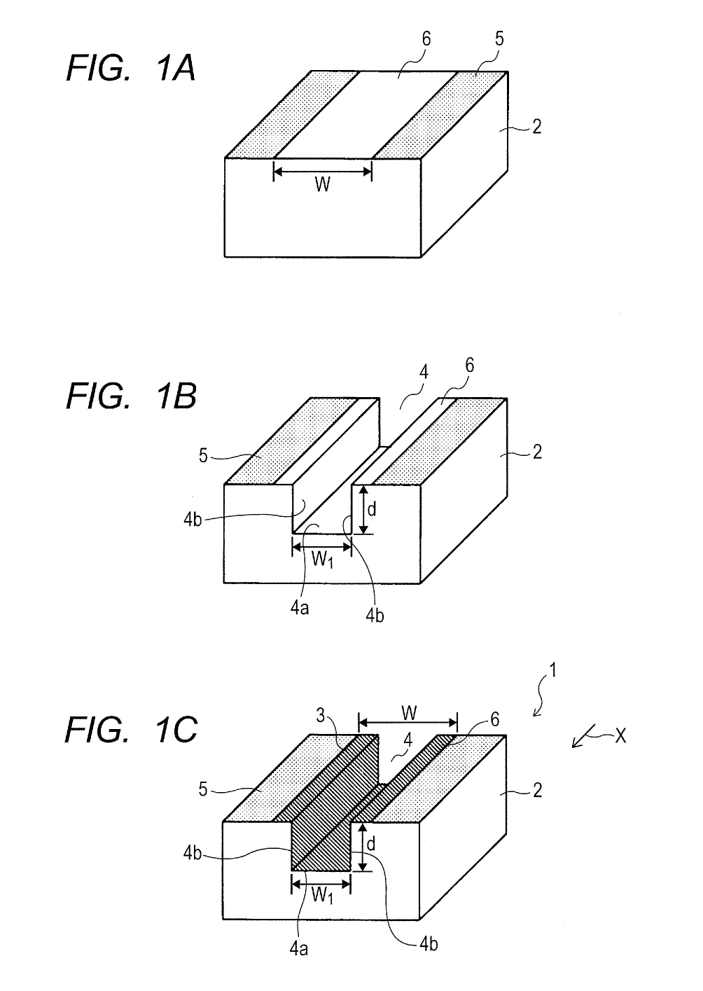

Now, the substrate according to the first embodiment of the present invention will be described below by referring to FIGS. 1A, 1B and 1C.

FIGS. 1A through 1C are schematic perspective views of a substrate according to the first embodiment of the present invention, illustrating the manufacturing steps thereof. FIG. 1C is a schematic perspective view illustrating an actual part of the substrate of this embodiment.

As illustrated in FIG. 1C, the substrate 1 of this embodiment has a substrate body 2 and a printed circuit 3 extending in a predetermined direction (to be referred to as “first direction X” hereinafter) on the substrate body 2. The printed circuit 3 is connected to a semiconductor element (not illustrated) arranged at the substrate body 2 and electric power that is supplied from a power source (not illustrated) to the substrate 1 is ultimately supplied to the semiconductor element by way of the printed circuit 3.

The substrate body 2 has a substrate surface 5 where a recess 4 is formed. The printed circuit 3 is formed in a region of the substrate surface 5 including the inner side surfaces (bottom surface 4a, lateral surfaces 4b) of the recess 4 (to be referred to as “circuit region 6” hereinafter).

In this embodiment, a single groove that extends along the first direction X is formed as the recess 4. The cross section of the groove represents a rectangular contour with a groove width W1 and a depth d.

Note that the expression of “the cross section of the groove” as used herein refers to a cross section obtained by cutting the groove by a plane that is perpendicular to the direction in which the groove extends. The expression of “the groove width” as used herein refers to the linear dimension of the groove in the direction that is perpendicular to both the direction in which the groove extends and the depth direction of the groove.

In this embodiment, an electric current flows through the printed circuit 3 along the first direction X. Therefore, the dimension of the printed circuit 3 in the direction perpendicular to the direction in which an electric current flows (i.e. the circuit width) is greater than that of a printed circuit formed on a flat surface because the printed circuit 3 is formed in the circuit region 6 including the bottom surface 4a and the lateral surfaces 4b.

More specifically, the circuit width of a printed circuit formed in the circuit region 6 of a substrate body 2 having a flat substrate surface (e.g., FIG. 1A) is equal to the width W of the circuit region. On the other hand, the circuit width of the printed circuit 3 formed in the circuit region 6 illustrated in FIG. 1C is expressed by W+2d. Thus, the circuit width of the printed circuit 3 of this embodiment is greater than that of a comparable printed circuit formed on a flat surface by 2d.

The electric resistance of a printed circuit is inversely proportional to the circuit width of the printed circuit. Therefore, the electric resistance of the printed circuit 3 of this embodiment is smaller than that of a printed circuit formed on a flat substrate surface. Thus, a large voltage can be applied to the semiconductor element (not illustrated) arranged at the substrate body 2 and the voltage being applied to the semiconductor element can be changed suddenly to a large extent.

The contour of the cross section of the recess 4 formed as a groove is not limited to a rectangular contour. Alternatively, the cross section of the recess 4 may represent a triangular contour or a trapezoidal contour, for instance. Additionally, the groove width W1 may vary relative to the first direction X or to the third direction Z.

The recess 4 may not necessarily be limited to a single groove. Alternatively, for example, a plurality of grooves that extend in the first direction X may be formed. If a total of N grooves are formed with a depth of d, the circuit width of the printed circuit 3 is increased by 2d×N.

Furthermore, the inside of the recess 4 may be totally or partly filled with an electroconductive material. With such an arrangement, an electric current flows not only through the printed circuit 3 but also through the electroconductive material and hence it can flow more easily.

Now, the method of manufacturing the substrate 1 will be described also by referring to FIGS. 1A through 1C.

Firstly, as illustrated in FIG. 1A, a plate-shaped substrate body 2 is prepared. Then, as illustrated in FIG. 1B, a single groove having a width W1 and a depth d is formed as recess 4 in the circuit region 6 of the substrate body 2. Subsequently, as illustrated in FIG. 1C, a printed circuit 3 is formed in the circuit region 6 that includes the bottom surface 4a and the lateral surfaces 4b of the recess 4. Now, the process of manufacturing the substrate 1 is completed.

The technique for forming the recess 4 may be selected appropriately depending on the material and the shape of the part of the plate-shaped substrate 2 where the recess 4 is to be formed.

If, for example, the part of the plate-shaped substrate 2 where the recess 4 is to be formed is made of Si, the recess 4 can be formed by means of a semiconductor processing technique. More specifically, a resist pattern is formed in the region of the substrate surface 5 other than the region where the recess 4 is to be formed by means of photolithography. Subsequently, the substrate surface 5 is etched by means of reactive ion etching (RIE). The resist pattern operates as mask and the recess 4 is formed in the substrate body 2. With such a semiconductor processing technique, a groove having a width W1 of 0.01 to 100 μm and a ratio of the depth d to the width W of 0.5 to 50 is formed.

If, on the other hand, the part of the plate-shaped substrate 2 where the recess 4 is to be formed is made of a ceramic material, the recess 4 can be formed by means of a machining technique, a ultrasonic processing technique or some other processing technique. More specifically, a groove having a width W1 of 10 to 1,000 μm and a ratio of the depth d to the width W of 0.5 to 20 can be formed in the substrate body 2 by means of blade dicing.

Techniques that can be used for forming the printed circuit 3 include metal sputtering, plating, chemical vapor deposition (CVD) and physical vapor deposition (PVD).

### Second Embodiment

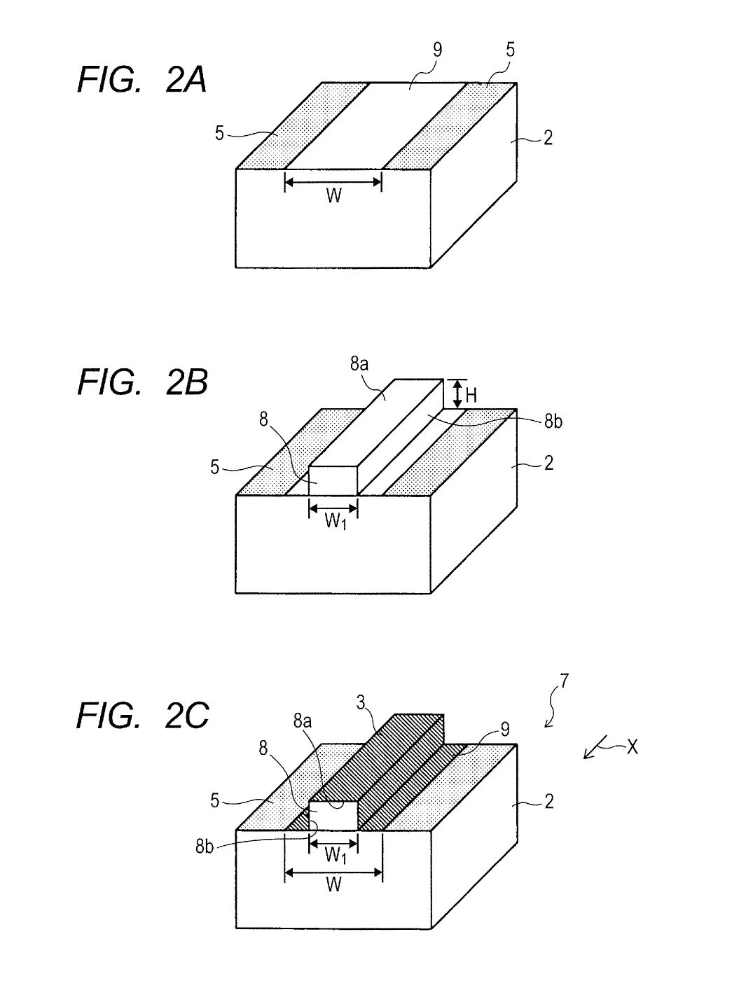

Now, the substrate according to the second embodiment of the present invention will be described below by referring to FIGS. 2A, 2B and 2C.

FIGS. 2A through 2C are schematic perspective views of a substrate according to the second embodiment of the present invention, illustrating the manufacturing steps thereof. FIG. 2C schematically illustrates an actual part of the substrate of this embodiment in perspective. In FIGS. 2A through 2C, the components that are the same as those illustrated in FIGS. 1A through 1C are denoted by the same reference symbols and will be described only briefly.

As illustrated in FIG. 2C, the substrate 7 of this embodiment has a substrate body 2 and a printed circuit 3. The substrate body 2 has a substrate surface 5 where a protrusion 8 is formed. The printed circuit 3 is formed in a region of the substrate surface 5 including the outer side surfaces (top surface 8a and lateral surfaces 8b) of the protrusion 4 (to be referred to as “circuit region 9” hereinafter).

In this embodiment, a single prism that extends along the first direction X is formed as the protrusion 8. The cross section of the prism represents a rectangular contour with a prism width W1 and a depth H.

Note that the expression of “the cross section of the prism” as used herein refers to a cross section obtained by cutting the prism by a plane that is perpendicular to the direction in which the prism extends. The expression of “the prism width” as used herein refers to the linear dimension of the prism in the direction that is perpendicular to both the direction in which the prism extends and the height direction of the prism.

In this embodiment, an electric current flows through the printed circuit 3 along the first direction X. Therefore, the circuit width of the printed circuit 3 is greater than that of a printed circuit formed on a flat surface because the printed circuit 3 is formed in the circuit region 9 including the top surface 8a and the lateral surfaces 8b of the protrusion 8.

More specifically, the circuit width of a printed circuit formed in the circuit region 9 of a substrate body 2 having a flat substrate surface (e.g., FIG. 2A) is equal to the width W of the circuit region 9. On the other hand, the circuit width of the printed circuit 3 formed in the circuit region 6 illustrated in FIG. 2C is expressed by W+2H. Thus, the circuit width of the printed circuit 3 of this embodiment is greater than that of a comparable printed circuit formed on a flat surface by 2H.

The electric resistance of a printed circuit is inversely proportional to the circuit width of the printed circuit. Therefore, the electric resistance of the printed circuit 3 of this embodiment is smaller than that of a printed circuit formed on a flat substrate surface. Thus, a large voltage can be applied to the semiconductor element (not illustrated) arranged at the substrate body 2 and the voltage being applied to the semiconductor element can be changed suddenly to a large extent.

The contour of the cross section of the protrusion 8 formed as a prism is not limited to a rectangular contour. Alternatively, the cross section of the protrusion 8 may represent a triangular contour or a trapezoidal contour, for instance. Additionally, the prism width W1 may vary relative to the first direction X or to the direction of height.

The protrusion 8 is not necessarily limited to a single prism. Alternatively, for example, a plurality of prisms that extend in the first direction X may be formed. If a total of N prisms are formed with a height of H, the circuit width of the printed circuit 3 is increased by 2H×N.

Furthermore, the protrusion 8 may be totally or partly made of an electroconductive material. With such an arrangement, an electric current flows not only through the printed circuit 3 but also through the electroconductive material and hence it can flow more easily.

This embodiment may be combined with the first embodiment. That is, a recess and a protrusion may be formed on the substrate surface 5 of the surface main body 2.

Now, the method of manufacturing the substrate 7 will be described also by referring to FIGS. 2A through 2C.

Firstly, as illustrated in FIG. 2A, a plate-shaped substrate body 2 is prepared. Then, as illustrated in FIG. 2B, a single prism having a width W1 and a depth H is formed as protrusion 8 in the circuit region 9 of the substrate body 2. Subsequently, as illustrated in FIG. 2C, a printed circuit 3 is formed in the circuit region 9 that includes the top surface 8a and the lateral surfaces 8b of the protrusion 8. Now, the process of manufacturing the substrate 1 is completed.

The technique for forming the protrusion 8 may be selected appropriately depending on the material and the shape of the circuit region 9 of the substrate body 2. For example, a technique of removing the region of the substrate surface 5 of the substrate body 2 other than the region where the protrusion 8 is to be produced may be employed. Then, the remaining part becomes the protrusion 8.

Alternatively, a new member may be fitted to the substrate surface 5 to produce the protrusion 8. For example, a photosensitive resin material may be applied to the substrate surface 5 and a technique of photolithography may be employed to remove the unnecessary part of the photosensitive resin material and produce a structure of the photosensitive resin material that is left as the protrusion 8 in the circuit region 9.

Techniques that can be used for forming the printed circuit 3 include metal sputtering, plating, chemical vapor deposition and physical vapor deposition.

### Third Embodiment

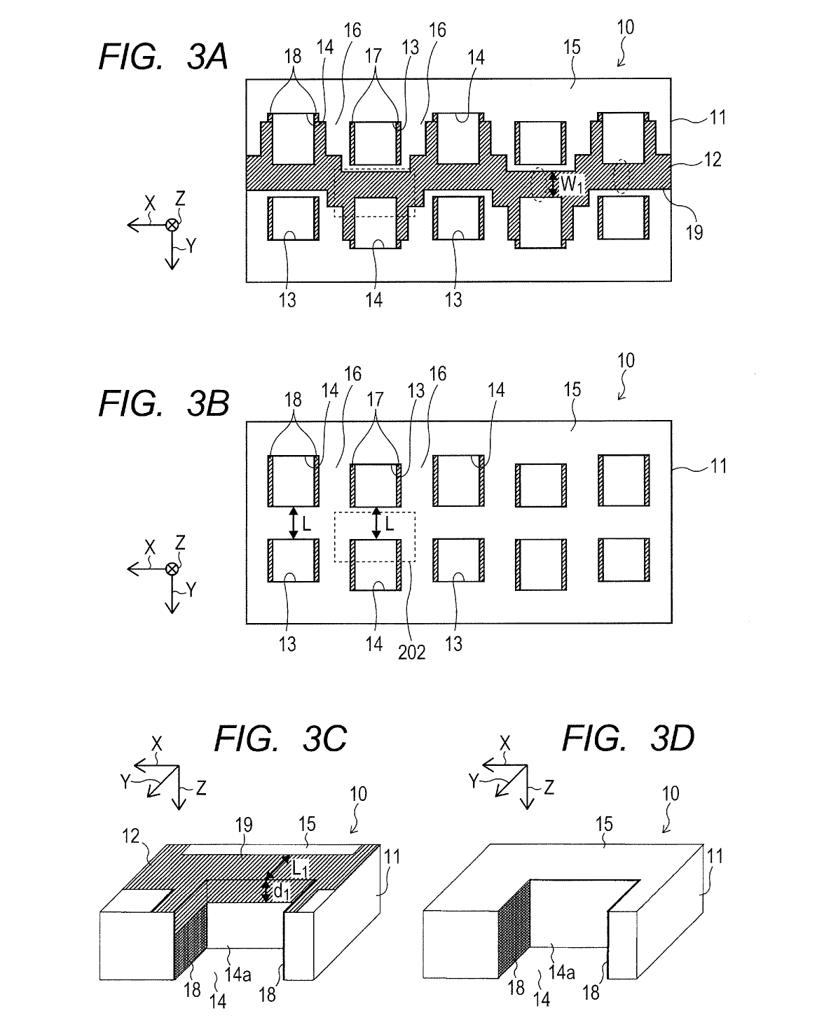

Now, the substrate according to the third embodiment of the present invention will be described below by referring to FIGS. 3A through 3D.

FIG. 3A is a schematic top view of the substrate according to this embodiment and FIG. 3B is a top view of the substrate illustrated in FIG. 3A from which the printed circuit is omitted, whereas FIG. 3C is an enlarged schematic perspective view of the part of the substrate enclosed by a dotted line illustrated in FIG. 3A and FIG. 3D is an enlarged schematic perspective view of the part of the substrate enclosed by a dotted line illustrated in FIG. 3B.

As illustrated in FIG. 3A, the substrate 10 of this embodiment has a substrate body 11 and a printed circuit 12 extending along the first direction X on the substrate body 11. The substrate body 11 has first through holes 13 and second through holes 14 that pass through the substrate body 11.

One of the openings of each of the first through holes 13 and one of the openings of each of the second through holes 14 are formed at one of the surfaces (to be referred to as “substrate surface 15” hereinafter) of the substrate body 11 and the first and second through holes 13 and 14 extend in the same direction from the substrate surface 15. Additionally, the first and second through holes 13 and 14 are formed side by side in the first direction.

The walls 16 separating the first and second through holes 13 and 14 are formed by a polarized piezoelectric material. First electrodes 17 are arranged at the first wall surfaces of the walls 16 defining the first through holes 13, whereas second electrodes 18 are arranged at the second wall surfaces of the walls 16 defining the second through holes 14.

The second electrodes 18 are connected to the printed circuit 12 and the first electrodes 17 are connected to the printed circuit (not illustrated) formed on the surface opposite to the substrate surface 15 of the substrate body 11. Electric power that is supplied from a power source (not illustrated) to the substrate 10 is ultimately supplied to the first electrodes 17 and the second electrodes 18 by way of the respective printed circuit. The walls 16 are deformed as a voltage is applied between the first electrodes and the second electrodes.

Substrates 10 having a configuration as described above are adopted for a type of liquid ejection heads that are referred to as piezoelectric type inkjet heads.

For instance, the first through holes 13 are employed as liquid storage chambers that communicate with ejection ports for ejecting liquid and store liquid to be ejected from the ejection ports, while the second through holes 14 are employed as air chambers into and from which air flows. Ink is supplied to the first through holes 13. The ink in the first through holes 13 is ejected from the ejection ports as the walls 16 are deformed to reduce the volumes of the first through holes 13.

With the substrate 10 of this embodiment, the printed circuit 12 is formed in a circuit region 19 that includes a part of the substrate surface 15 and a part of the inner wall surface 14a of each of the second through holes 14.

With known substrates to be used for piezoelectric type inkjet heads, the printed circuit to be connected to the second electrodes 18 is formed only in a region of the substrate surface 15 that is separated from the opening edges of the first and second through holes 13, 14. Therefore, the circuit width of the printed circuit 12 is inevitably made small when the substrate surface 15 does not have a sufficiently large width extending in the second direction Y that is perpendicular to the first direction X.

When, for example, some of the openings of the second through holes 14 are formed adjacent to the corresponding ones of the openings of the first through holes 13 in the second direction Y, the largest value of the width of the printed circuit of any known substrate is defined by the gap L between the first through holes 13 and the second through holes 14 that are arranged adjacently in the second direction Y. In actuality, the printed circuit is separated from the opening edges of the first through holes to prevent the printed circuit from short-circuiting with the first electrodes 17 so that the circuit width of the printed circuit has to be made equal to L1 that is smaller than the gap L.

To the contrary, with this embodiment, the printed circuit 12 is formed also at a part of each of the inner walls surfaces 14a of the second through holes 14. Now, take an instance where the part of the printed circuit 12 that is formed at the inner wall surfaces 14a of each of the second through holes 14 has a dimension d1 in the third direction Z along which the second through holes 14 extend (see FIG. 3C). Then, the circuit width of the printed circuit 12 is greater than the circuit width of any comparable known printed circuit that is formed only at a part of the substrate surface 15 by d1.

The electric resistance of a printed circuit is inversely proportional to the circuit width of the printed circuit. Therefore, the electric resistance of the printed circuit 12 of this embodiment is smaller than that of a printed circuit formed only at a part of the substrate surface 15. Thus, a large voltage can be applied to the walls 16 and the voltage being applied to the walls 16 can be changed suddenly to a large extent.

Techniques that can be used for forming the printed circuit 12 on the inner wall surfaces 14a of the second through holes 14 include sputtering, oblique vacuum deposition, plating, chemical vapor deposition and physical vapor deposition. A thin seed layer may be formed in a desired region by means of a lift-off technique prior to forming the printed circuit 12. The printed circuit 12 can be formed to a desired thickness by forming a seed layer in advance.

### Fourth Embodiment

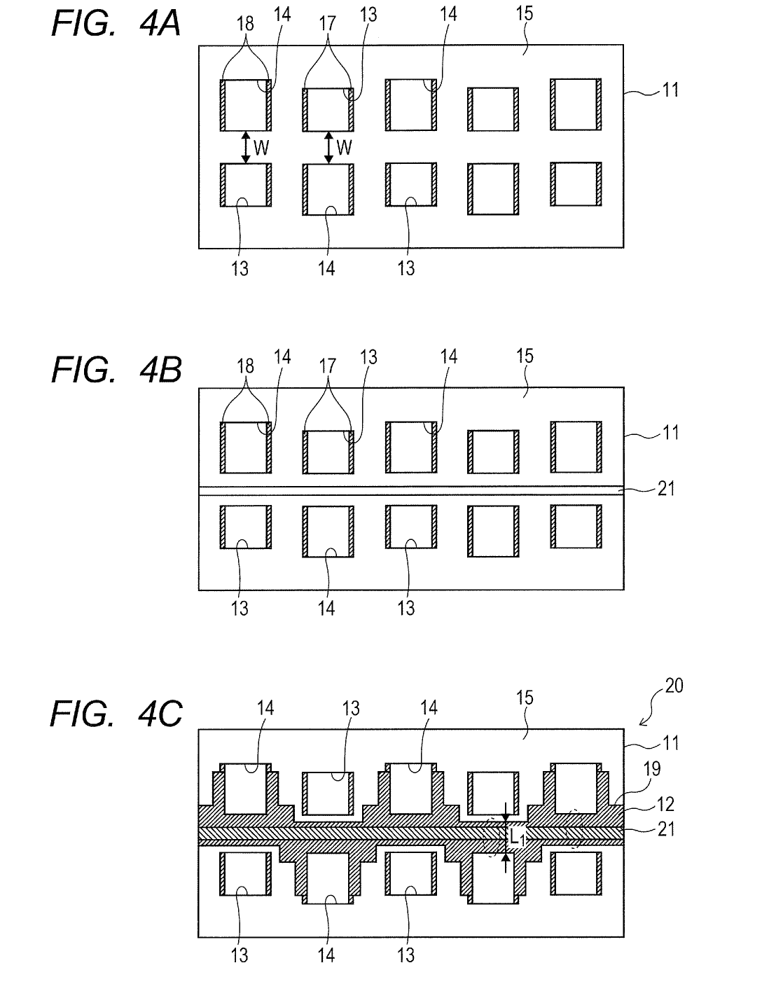

Now, the substrate according to the fourth embodiment of the present invention will be described below by referring to FIGS. 4A through 4C.

FIGS. 4A through 4C are schematic top views of a substrate according to the fourth embodiment of the present invention, illustrating the manufacturing steps thereof.

FIG. 4C is a schematic top view illustrating an actual part of the substrate of this embodiment. Like substrates 10 having the same configuration as that of the third embodiment (see FIG. 3A), substrates 10 having a configuration as that of this embodiment are adopted for a type of liquid ejection heads that are referred to as piezoelectric type inkjet heads.

In FIGS. 4A through 4C, the components that are the same as those illustrated in FIGS. 3A through 3C are denoted by the same reference symbols and will be described only briefly.

As illustrated in FIG. 4C, the substrate 20 of this embodiment includes a substrate body 11 having a substrate surface 15 and a printed circuit 12 extending in the first direction X on the substrate surface 15. A recess 21 is formed in the circuit region 19 of the substrate surface 15. More specifically, the printed circuit 12 is formed in the circuit region 19 that includes the bottom surface and the lateral surfaces of the recess 21.

As described above for the first embodiment, the circuit width of the printed circuit formed on the substrate surface where a recess is formed is greater than the circuit width of a comparable printed circuit formed on a flat substrate surface by twice of the depth of the recess. In short, the circuit width of the printed circuit 12 of this embodiment is greater than that of the printed circuit 12 (FIG. 3A) of the third embodiment because it is formed on the substrate surface 15 where a recess 21 is formed. Thus, the electric resistance of the printed circuit 12 of this embodiment is relatively low.

The recess 21 may be replaced by a protrusion formed in the circuit region 19 of the substrate surface 15. Because the circuit region 19 includes the top surface and the lateral surfaces of such a protrusion, the circuit width of the printed circuit 12 is increased and the electric resistance of the printed circuit 12 is reduced, as described above for the second embodiment.

Techniques that are the same as those described above for the first and second embodiments can be used to form a recess 21 or a protrusion on the substrate surface 15 and hence they will not be described here repeatedly. Techniques that can be used for forming a printed circuit are also the same as those described for the first through third embodiments and are hence omitted.

### Fifth Embodiment

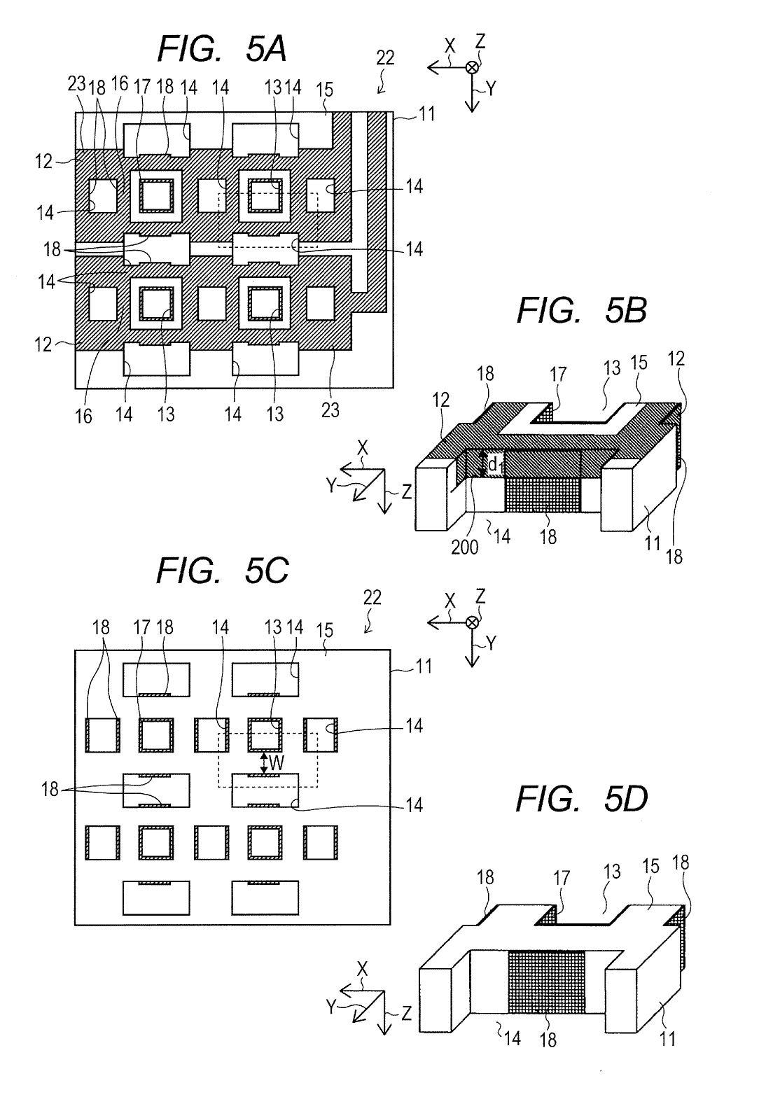

Now, the substrate according to the fifth embodiment of the present invention will be described below by referring to FIGS. 5A through 5D.

FIG. 5A illustrates a schematic top view of a substrate according to the fifth embodiment. FIG. 5B is an enlarged schematic perspective view of the part of the substrate enclosed by a dotted line illustrated in FIG. 5A.

FIG. 5C is a schematic top view of the substrate illustrated in FIG. 5A from which the printed circuit is omitted. FIG. 5D is an enlarged schematic perspective view of the part of the substrate enclosed by a dotted line illustrated in FIG. 5C.

The components of this embodiment that are the same as those illustrated in FIGS. 3A through 3D and FIGS. 4A through 4C are denoted by the same reference symbols and will be described only briefly.

As illustrated in FIG. 5A, the substrate 22 of this embodiment includes a substrate body 11 having a plurality of first through holes 13 and a plurality of second through holes 14 respectively and a printed circuit 12 extending in the first direction X on the substrate body 11.

One of the openings of each of the first through holes 13 and one of the openings of each of the second through holes 14 are formed at one of the surfaces (to be referred to as “substrate surface 15” hereinafter) of the substrate body 11 and the first and second through holes 13 and 14 extend in the same direction from the substrate surface 15. Additionally, a total of four second through holes 14 are formed around a single first through hole 13 so as to sandwich the first through hole 13 both in the first direction X and the second direction Y. Note that the second direction Y is a direction that runs in parallel with the substrate surface 15 and perpendicularly intersects the first direction X.

The walls 16 between the first and second through holes 13 and 14 are formed by a polarized piezoelectric material. First electrodes 17 are arranged at the first wall surfaces of the walls 16 defining the first through holes 13, whereas second electrodes 18 are arranged at the second wall surfaces of the walls 16 defining the second through holes 14.

The second electrodes 18 are connected to the printed circuit 12 and the first electrodes 17 are connected to the printed circuit (not illustrated) formed on the surface opposite to the substrate surface 15 of the substrate body 11. Electric power that is supplied from a power source (not illustrated) to the substrate 10 is ultimately supplied to the first electrodes 17 and the second electrodes 18 by way of the respective printed circuits. The walls 16 are deformed as a voltage is applied between the first electrodes and the second electrodes. Substrates 10 having a configuration as described above are adopted for a type of liquid ejection heads that are referred to as piezoelectric type inkjet heads. The first through holes 13 are employed as liquid storage chambers that communicate with ejection ports for ejecting liquid and store liquid to be ejected from the ejection ports, while the second through holes 14 are employed as air chambers into and from which air flows. Thus, ink is supplied to the first through holes 13. The ink in the first through holes 13 is ejected from the ejection ports as the walls 16 are deformed to reduce the volumes of the first through holes 13.

In the substrate 10 of the third embodiment (FIG. 3A), the walls between the first through holes 13 and the second through holes 14 in the first direction X are deformed. In the substrate 22 of this embodiment, on the other hand, the walls between the first through holes 13 and the second through holes both in the first direction X and in the second direction Y are deformed. Thus, the substrate 22 of this embodiment can eject ink in the first through holes 13 more strongly than the substrate 10 of the third embodiment.

The printed circuit 12 is formed in a circuit region 23 that includes a part of the substrate surface 15 and a part of the inner wall surface 14a of each of the second through holes 14. Therefore, the circuit width of the printed circuit 12 of the substrate according to this embodiment is greater than that of a comparable substrate where the printed circuit is formed only in a region separated from the opening edges of the first and second through holes 13 and 14.

Take an instance where the part of the printed circuit 12 that is formed at the inner wall surfaces 14a of each of the second through holes 14 has a dimension d1 in the third direction Z along which the second through holes 14 extend (see FIG. 5B). Then, the circuit width of the printed circuit 12 is greater than the circuit width of any comparable known printed circuit that is formed only at a part of the substrate surface 15 by d1.

The electric resistance of a printed circuit is inversely proportional to the circuit width of the printed circuit. Therefore, the electric resistance of the printed circuit 12 of this embodiment is smaller than that of a known printed circuit formed only at a part of the substrate surface 15.

The electric resistance of a printed circuit is inversely proportional to the circuit width of the printed circuit. Accordingly, the electric resistance of the printed circuit 12 of this embodiment is smaller than that of the printed circuit formed on the flat substrate surface.

Thus, with the substrate 22 of this embodiment having a large number of through holes, a large voltage can be applied to the walls 16 and the voltage being applied to the semiconductor elements arranged on the substrate can be changed suddenly to a large extent even if the substrate body 11 has a relatively small substrate surface 15.

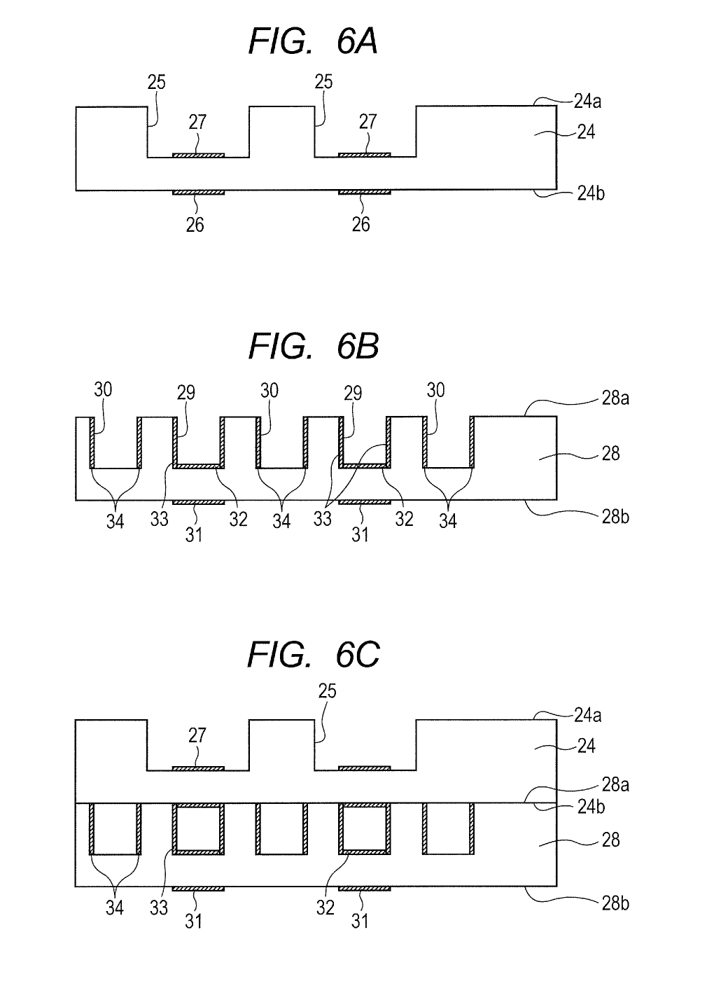

Now, an exemplar method that can be used for manufacturing the substrate 22 will be described below by referring to FIGS. 6A through 6C. FIGS. 6A through 6C are cross-sectional views of the substrate illustrating a method for manufacturing the substrate 22.

Firstly, a first member made of PZT (lead zirconate titanate; to be referred to as “first PZT member 24” hereinafter) is prepared. First grooves are formed in the first surface 24a of the first PZT member 24 as illustrated in FIG. 6A. Techniques that can be used to form the first grooves 25 include blade dicing.

Each of the first grooves 25 is formed for one of a pair of second through hole 14 that sandwich a first through hole 13 in the second direction Y of the substrate 22 illustrated in FIG. 5A.

Then, first electrode films 26 are formed on parts of the second surface 24b that is opposite to the first surface 24a and then second electrode films 27 are formed respectively on the bottom surfaces of the first grooves 25. When forming the first and second electrode films 26 and 27, the center of each of the first electrode films 26 is desirably aligned with the center of the corresponding one of the second electrode films 27 in the depth direction of the groove 25.

Techniques that can be used for forming the first and second electrode films 26 and 27 include lift-off and plating.

Subsequently, a second PZT member 28 that differs from the first PZT member 24 is prepared. As illustrated in FIG. 6B, second grooves 29 and third grooves 30 are alternately formed on the first surface 28a of the second

PZT member 28. The second and third grooves 29 and 30 are formed by blade dicing.

The second grooves 29 are formed for the first through holes 13 of the substrate 22 illustrated in FIG. 5A and the third grooves 30 are formed for the second through holes 14 that sandwich the first through holes 13 in the first direction X of the substrate 22 illustrated in FIG. 5A.

Thereafter, third electrode films 31 are formed on parts of the second surface 28b of the second PZT member 28 that is opposite to the first surface 28a. Additionally, forth electrode films 32 are formed respectively on the bottom surfaces of the second grooves 29 and fifth electrode films 33 are formed respectively on the lateral surfaces of the second grooves 29, while sixth electrode films 34 are formed respectively on the lateral surfaces of the third grooves 30. When forming the third and fourth electrode films 31 and 32, the center of each of the third electrode films 26 is desirably aligned with the center of the corresponding one of the fourth electrode films 27 in the depth direction of the groove 29.

Subsequently, as illustrated in FIG. 6C, the second surface 24b of the first PZT member 24 is bonded to the first surface 28a of the second PZT member 28. At this time, the first and second PZT members 24 and 28 are aligned with each other such that the each of the first electrode film 26 is disposed right opposite to the corresponding one of the fourth electrode film 32. Bonding techniques using an insulating adhesive agent can be used for bonding the first and second PZT members 28 to each other.

The second surface 28b of a second PZT member 28 that is different from the second PZT member 28 illustrated in FIG. 6C is bonded to the first surface 24a of the first PZT member 24. The substrate body 11 illustrated in FIG. 5A is obtained as a result of bonding a plurality of first and second PZT members 24, 28.

Thereafter, a printed circuit 12 is formed on the substrate body 11 to complete the process of manufacturing the substrate 22 of this embodiment. Since the technique of forming the printed circuit 12 is the same as the one describe above for the first through third embodiment, it will not be describe here repeatedly.

### Sixth Embodiment

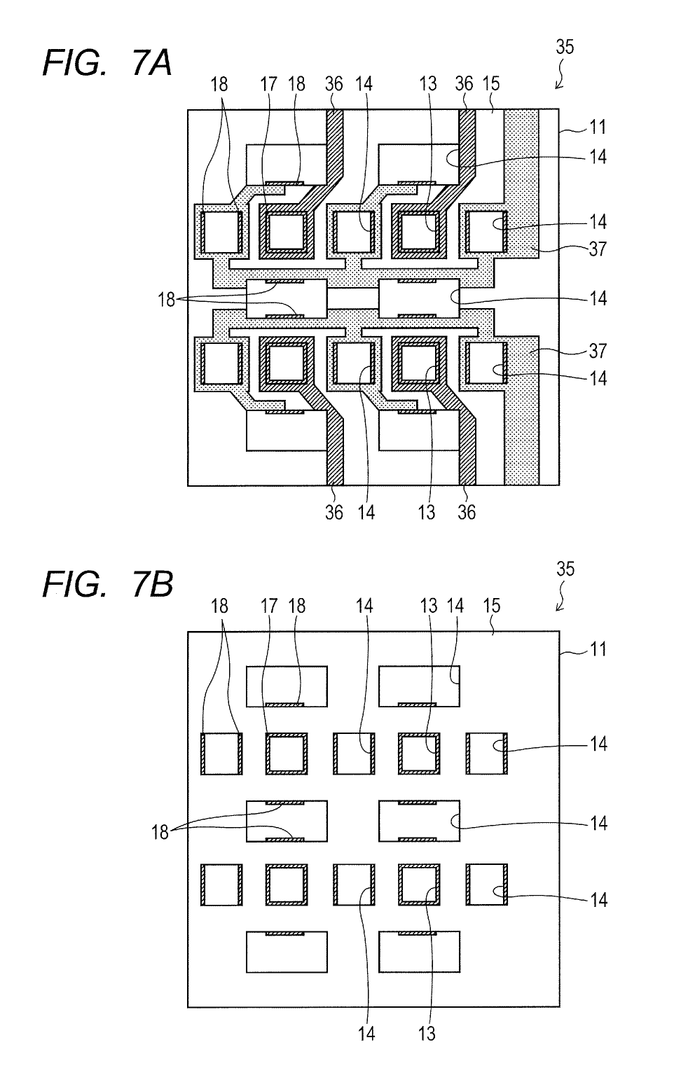

Now, the substrate according to the sixth embodiment of the present invention will be described below by referring to FIGS. 7A and 7B.

FIGS. 7A and 7B are respectively a schematic top view of substrate according to the sixth embodiment and a schematic top view of the substrate from which the printed circuit is omitted.

As illustrated in FIG. 7A, the substrate 35 of this embodiment includes a substrate body 11 where a plurality of first through holes 13 and a plurality of second through holes 14 are formed alternately. A first electrode 17 is formed on the inner wall surface of each of the first through holes 13, while a second electrode 18 is formed at part of the inner wall surface of each of the second through holes 14.

Note that the substrate body 11 and the first and second electrodes 17, 18 of this embodiment are the same as those illustrated in FIG. 5C. Therefore, the components that are the same as those illustrated in FIGS. 5A through 5C are denoted by the same reference symbols and will be described only briefly.

As illustrated in FIG. 7A, first and second printed circuits 36, 37 are formed on the substrate surface 15 of the substrate body 11. The first printed circuits 36 are connected to the first electrodes 17, while the second printed circuits 37 are connected to the second electrodes 18.

The first and second printed circuits 36 and 37 are formed also in parts of the inner walls of the second through holes 14 where the second electrodes 18 are not formed. Thus, the circuit width of the first printed circuits 36 and that of the second printed circuits 37 are relatively large and hence the electric resistance of the first printed circuits 36 and that of the second printed circuits 37 are relatively small. As a result, a high voltage can be applied between the first and second electrodes 17 and 18 and the voltage being applied between the first and second electrodes 17 and 18 can be changed suddenly to a large extent.

The technique for manufacturing the printed circuits 36 and 37 is the same as the one described for the first through third embodiments and hence will not be described here repeatedly.

### Seventh Embodiment

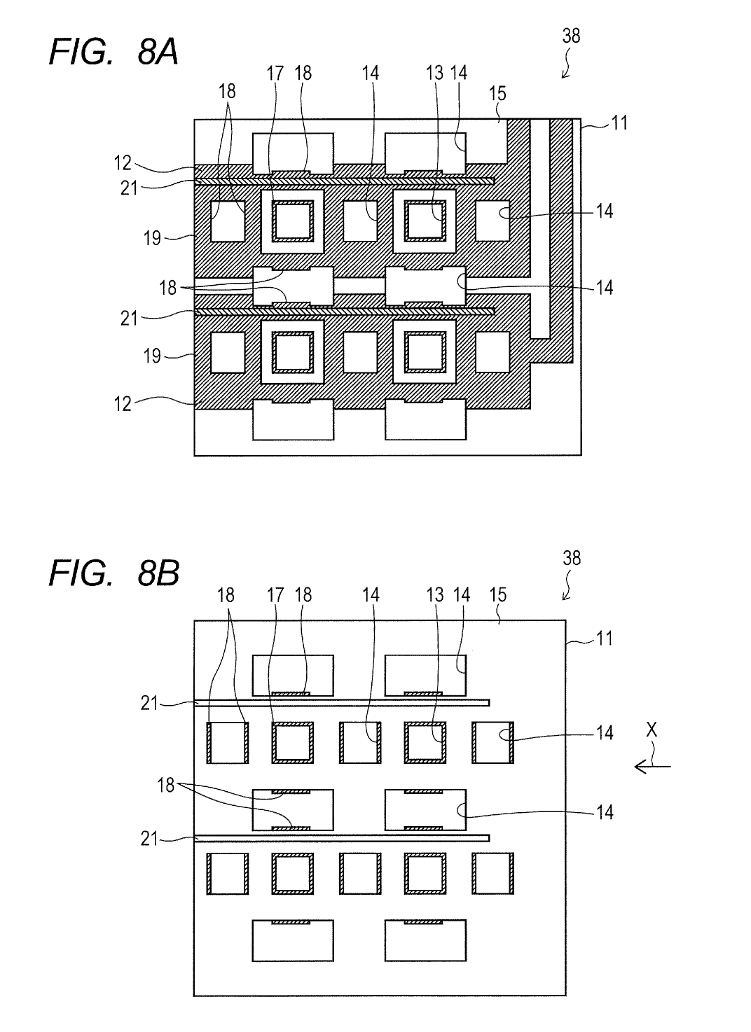

Now, the substrate according to the seventh embodiment of the present invention will be described below by referring to FIGS. 8A and 8B.

FIGS. 8A and 8B are respectively a schematic top view of substrate according to the seventh embodiment of the present invention and a schematic top view of the substrate from which the printed circuit is omitted.

As illustrated in FIG. 8A, the substrate 38 of this embodiment includes a substrate body 11 where a plurality of first through holes 13 and a plurality of second through holes 14 are formed alternately and printed circuits 12 that extend in the first direction X on the substrate surface 15. Recesses 21 are formed in the circuit regions 19 of the substrate surface 15. In other words, the printed circuits 12 of this embodiment are formed in the circuit regions 19 that include the inner lateral surfaces of the recesses 21.

The substrate body 11 and the first and second electrodes 17 and 18 of this embodiment are the same as those illustrated in FIG. 5C and FIG. 7B except the recesses 21. Therefore, the components that are the same as those illustrated in FIGS. 5A through 5C and FIGS. 7A and 7B will not be described here repeatedly.

The recesses 21 are typically grooves extending along the first direction X. Techniques that can be used to form the grooves include blade dicing.

The technique for forming the printed circuits 12 is the same as the one described for the first through third embodiments and hence will not be described here repeatedly.

As described above for the first embodiment, the circuit width of the printed circuits are greater than the circuit width of a comparable printed circuit formed on a flat substrate surface by twice of the depths of the recesses. In short, the circuit width of the printed circuit 12 of this embodiment is greater than that of the printed circuit 12 (FIG. 3A) of the third embodiment because it is formed on the substrate surface 15 where a recess 21 is formed. Thus, the electric resistance of the printed circuit 12 of this embodiment can be made relatively low. As a result, a high voltage can be applied between the first and second electrodes 17 and 18 and the voltage being applied between the first and second electrodes 17 and 18 can be changed suddenly to a large extent.

The recesses 21 may be replaced by protrusions formed in the circuit regions 19 of the substrate surface 15. Because the circuit regions 19 include the top surfaces and the lateral surfaces of such protrusions, the cross sections of the printed circuits 12 are increased and the electric resistances of the printed circuits 12 are reduced, as described above for the second embodiment.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-279771, filed Dec. 21, 2011, which is hereby incorporated by reference herein in its entirety.

What is claimed is:

1. A substrate comprising:
a substrate body having a semiconductor element formed thereon and at least either a recess or a protrusion formed on the surface thereof; and
a printed circuit formed on the substrate body and connected to the semiconductor element;
the printed circuit being formed in a region of the surface of the substrate including at least either the inner side surfaces of the recess or the outer side surfaces of the protrusion.

2. The substrate according to claim 1, wherein
the printed circuit formed at least either on the inner side surfaces of the recess or on the outer side surfaces of the protrusion and the printed circuit formed on the surface are continuous with each other.

3. A substrate comprising:
a substrate body having a semiconductor element and a through hole; and
a printed circuit formed on the substrate body and connected to the semiconductor element;
the printed circuit being formed on the surface of the substrate body where one of the openings of the through hole and on the inner wall surface of the through hole.

4. The substrate according to claim 3, wherein
the printed circuit formed on the surface and the printed circuit formed on the inner wall surface of the through hole are continuous with each other.

5. The substrate according to claim 3, wherein
at least either a recess or a protrusion is formed on the surface of the substrate and the printed circuit is formed in a region including the inner side surfaces of the recess or the outer side surfaces of the protrusion.

6. The substrate according to claim 5, wherein
the printed circuit formed on the surface, the printed circuit formed on the inner wall surface of the through hole and the printed circuit formed on the inner side surfaces of the recess or on the outer side surfaces of the protrusion are continuous with each other.

7. A liquid ejection head comprising a substrate as claimed in claim 1, wherein
the substrate body has a liquid storage chamber configured to communicate with an ejection port for ejecting liquid and store the liquid to be ejected from the ejection port; and
the semiconductor element includes a wall forming the liquid storage chamber at least a part of which is formed by a piezoelectric material, a first electrode arranged on a first wall surface of the wall forming the liquid storage chamber and a second electrode arranged on a second wall surface opposite to the first wall surface of the wall;
the printed circuit being connected to either the first electrode or the second electrode such that the wall is deformed to eject the liquid in the inside of the liquid storage chamber from the ejection port as a voltage is applied between the first electrode and the second electrode.

8. A liquid ejection head comprising a substrate as claimed in claim 3, wherein
the substrate body has a liquid storage chamber configured to communicate with an ejection port for ejecting liquid and store the liquid to be ejected from the ejection port; and
the semiconductor element includes a wall forming the liquid storage chamber at least a part of which is formed by a piezoelectric material, a first electrode arranged on a first wall surface of the wall forming the liquid storage chamber and a second electrode arranged on a second wall surface opposite to the first wall surface of the wall;
the printed circuit being connected to either the first electrode or the second electrode such that the wall is deformed to eject the liquid in the inside of the liquid storage chamber from the ejection port as a voltage is applied between the first electrode and the second electrode.

9. The liquid ejection head as claimed in claim 8, wherein
the second wall surface is a part of the surface forming the through hole.

10. A method of manufacturing a substrate comprising:
preparing a substrate body having at least either a recess or a protrusion formed on the surface thereof and a semiconductor element formed therein; and
forming a printed circuit continuously in a region including at least either the inner side surfaces of the recess or the outer side surfaces of the protrusion and the surface of the substrate body.

11. A method of manufacturing a substrate comprising:
preparing a substrate body where a semiconductor element and a through hole are formed; and
forming a printed circuit continuously in a region including a part of the surface of the substrate body where one of the openings of the through hole is formed and the inner wall surface of the through hole.

12. A method of manufacturing a substrate comprising:
preparing a substrate body having at least either a recess or a protrusion formed on the surface thereof, a semiconductor element and a through hole formed therein; and
forming a printed circuit continuously in a region including at least either the inner side surfaces of the recess or the outer side surfaces of the protrusion, the surface of the substrate body and the inner wall surface of the through hole.
